(19) United States
(12) Patent Application Publication
(10) Pub. No.: US 2012/0296583 A1
(43) Pub. Date: Nov. 22, 2012

(54) TEST CARD AND MOTHERBOARD MONITORING SYSTEM

(75) Inventor: WEI-DONG CONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/167,728

(22) Filed: Jun. 24, 2011

(30) Foreign Application Priority Data
May 16, 2011 (CN) 201110125284.3

(51) Int. Cl. G06F 19/00; G01R 31/00

(52) U.S. Cl. 702/58

(57) ABSTRACT

An exemplary test card includes a display unit for displaying a real time status of a number of electric power supply modules of a motherboard, and a programmable logic chip. The display unit includes at least one seven segment LED display. The programmable logic chip gains an effective data of the real time status, and drives the display unit to display the real time status based on the effective data. The real time status can indicate a normal working status, or an abnormal working status if one or more of the power supply modules is not working normally.

### BACKGROUND

1. Technical Field

The present disclosure relates to a test card with digital display function and a motherboard monitoring system having such test card.

2. Description of Related Art

A core component of a computer is a motherboard with which all other parts (i.e. display device, keyboard, mouse, etc) are connected. The motherboard includes a number of working elements (e.g. CPU, video card, network card, memory, etc.). Each of the working elements has a safe working voltage which may be different to all other working voltages. When there is a voltage supply problem, a loudspeaker of the motherboard produces a sound to make a warning or an indicator light flashes to give a warning.

However, there are many working elements on the motherboard, and the said warning usually leaves the user confused. The user cannot quickly find which working element is experiencing a problem. Accordingly, the problem can not be solved quickly, and working efficiency decreases.

Therefore, what is needed is a new test card and a motherboard monitoring system having such a test card that can overcome the described limitations.

### BRIEF DESCRIPTION OF THE DRAWINGS

FIG. 1 is a block diagram of a motherboard monitoring system according to an exemplary embodiment.

FIG. 2 is a block diagram of a programmable logic chip of the motherboard monitoring system of FIG. 1.

### DETAILED DESCRIPTION

Embodiments will now be described in detail with reference to drawings.

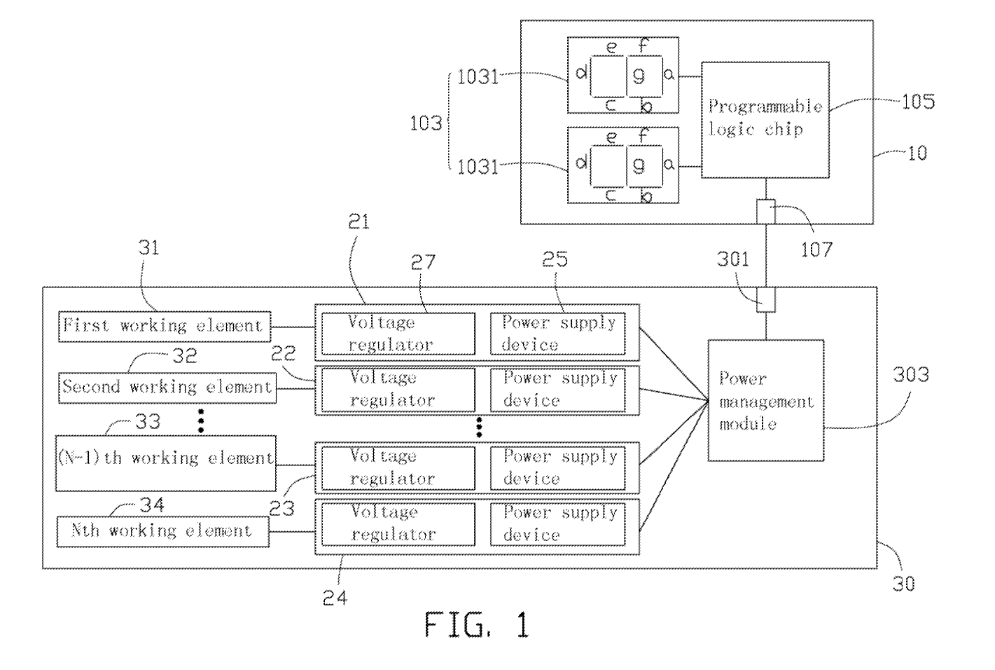

Referring to FIG. 1, a motherboard monitoring system 100 includes a test card 10 and a motherboard 30 electrically connected to the test card 10. The motherboard monitoring system 100 is configured for monitoring the real time status of a plurality of power supply modules (e.g. a first electric power supply module 21, a second electric power supply module 22 . . . an (N−1)th electric power supply module 23, and an Nth electric power supply module 24, (wherein N is an integer greater than 4)) arranged on the motherboard 30.

The test card 10 includes a display unit 103 and a programmable logic chip 105 electrically connected to the display unit 103.

The display unit 103 is configured for displaying the real time status of the electric power supply modules. The display unit 103 includes at least one seven segment LED display 1031 which includes a LED a, a LED b, a LED c, a LED d, a LED e, a LED f, and a LED g. The at least one seven segment LED display 1031 displays the real time status of the electric power supply modules based on preset display information. The real time status display includes a normal working status and an abnormal working status if one of the electric power supply modules is not working normally. In the present embodiment, there are two seven segment LED displays 1031.

The programmable logic chip 105 is electrically connected to the motherboard 30 via an interface 107 on the test card 10. The programmable logic chip 105 is configured for gaining an effective data concerning the real time status of the electric power supply modules from the motherboard 30, and driving the display unit 103 to display the real time status of the electric power supply modules based on that effective data. In the present embodiment, the programmable logic chip 105 is a chip capable of recognizing and distinguishing an SGPIO signal.

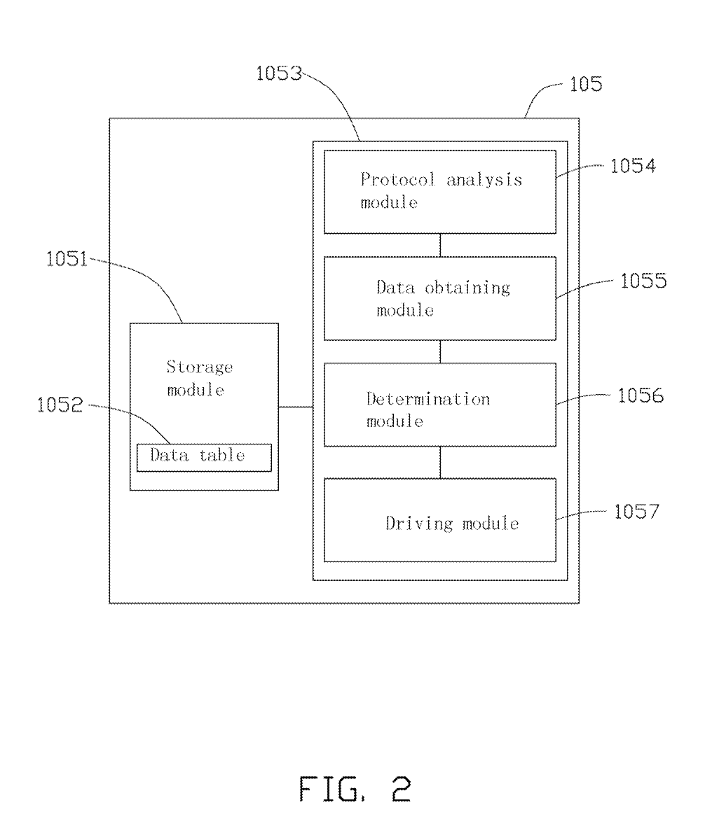

Referring to FIG. 2, the programmable logic chip 105 includes a storage module 1051 and a control unit 1053 electrically connected to the motherboard via the interface 107 for controlling the display unit 103. For convenience in controlling the display unit 103, when the control level is a high logic level at 1, then the LED is turned on, and when the control level is a low logic level at 0, the LED is turned off. For example, when the two seven segment LED displays 1031 display “02”, the controlling logic value of the two seven segment LED displays 1031 is “1111110-1101101”. In other embodiments, it may be that when the LED is turned on, the control level is a low logic level at 0, and when the LED is turned off, the control level is a high logic level at 1. In such a case as that, when the two seven segment LED displays 1031 display “02”, the controlling logic value is “0000001-0010010”.

The storage module 1051 is electrically connected to the control unit 1053, and includes a data table 1052. The data table 1052 includes a plurality of preset effective data and a plurality of preset controlling logic values for the at least one seven segment LED display 1031 corresponding to the preset effective data, respectively.

The control unit 1053 includes a protocol analysis module 1054, a data obtaining module 1055 electrically connected to the protocol analysis module 1054, a determination module 1056 electrically connected to the data obtaining module 1055, and a driving module 1057 electrically connected to the determination module 1056.

The protocol analysis module 1054 is configured for analyzing a real time status signal of the electric power supply modules from the motherboard 30 based on an SGPIO protocol, and determining the effective data of the real time status signal.

The data obtaining module 1055 is configured for obtaining the effective data from the protocol analysis module 1054, and transmitting the effective data to the determination module 1056.

The determination module 1056 is configured for determining the effective data from the data obtaining module 1055, and finding a corresponding controlling logic value for the at least one seven segment LED display 1031, which corresponds to the effective data, and then transmitting that controlling logic value to the driving module 1057.

The driving module 1057 is configured for driving the at least one seven segment LED display 1031 to display the real time status, either that a normal working status is in existence, or that an abnormal working status applies.

The motherboard 30 is electrically connected to the programmable logic chip 105 via the interface 301 on the motherboard 30. In the present embodiment, the interface 301 is electrically connected to the interface 107 via an SGPIO bus.

The motherboard 30 includes a power management module 303 electrically connected to the programmable logic chip 105 via the interface 301, the plurality of the power supply modules, a plurality of working elements electrically connected to the respective power supply modules (e.g. a first working element 31, a second working element 32, an (N−1)th working element 33, and an Nth working element 34 (wherein N is a whole number larger than 4)). In the present embodiment, the first working element 31 is a CPU, the second working element 32 is a memory, the (N−1)th working element 33 is a video card, and the Nth working element 34 is a sound card. In other embodiments, the working elements may be a network card, a south bridge, or a north bridge, etc.

The power management module 303 is configured for transmitting power control signals to the electric power supply modules, such that the electric power supply modules can be activated.

Each of the electric power supply modules is configured for supplying electric power to a corresponding working element. Each of the electric power supply modules includes a power supply device 25 electrically connected to the power management 303 and a voltage regulator 27 electrically connected between the power supply device 25 and its corresponding working element.

The power supply device 25 receives the power control signal, and supplies a first voltage to the corresponding voltage regulator 27 based on the power control signal. When the first voltage stabilizes, the power supply device 25 will output a first voltage stability signal to the power management module 303, confirming that the first voltage is stable.

When the power management module 303 receives the first voltage stability signal, the power management module 303 will output an enable signal to the corresponding voltage regulator 27. When there is a fault or some other disorder with the power supply device 25, and the power management module 303 does not receive the first voltage stability signal within a predetermined time, the power management module 303 may determine that there is a problem with the corresponding power supply device 25. Then, the power management module 303 generates a real time status signal of the corresponding power supply device 25, and transmits the real time status signal of the corresponding power supply device 25 to the programmable logic chip 105.

Each of the voltage regulators 27 is electrically connected to the power management module 303 in order to receive an enable signal. When the voltage regulator 27 receives an enable signal, the voltage regulator 27 will regulate the first voltage to a second voltage (i.e. a working voltage which is correct for the corresponding working element), and output a second voltage stability signal to the management module 303 when the second voltage has become stable. When there is a problem with the voltage regulator 27, and the management module 303 does not receive the second voltage stable signal within a predetermined time, the power management module 303 may determine that there is a problem with the corresponding voltage regulator 27. Then, the power management module 303 generates a real time status signal of the corresponding voltage regulator 27, and transmits the real time status signal of the corresponding voltage regulator 27 to the programmable logic chip 105.

In the present embodiment, there are nine electric power supply modules. When the display unit 103 displays “00”, it signifies that the all of the nine power supply modules are in normal working status. When the display unit 103 displays “01”, it means that there is a problem with the power supply device 25 of the first electric power supply module 21. When “10” is displayed, it means that there is a problem with the voltage regulator 27 of the first electric power supply module 21. When “02” is displayed, it means that there is a problem with the power supply device 25 of the second electric power supply module 22. When the display unit 103 displays “20”, it means that there is a problem with the voltage regulator 27 of the second electric power supply module 22. And so on and so forth, when the display unit 103 displays “09”, it means that there is a problem with the power supply device 25 of the ninth electric power supply module 24. When the display unit 103 displays “90”, it means that there is a problem with the voltage regulator 27 of the ninth electric power supply module 24.

As an example using the voltage regulator 27 of the second electric power supply module 22 when it has a problem, a working process of the programmable logic chip 105 would proceed as follows.

For clearly showing the data table 1052, a table 1 is given. Understandably, the data in the table 1 can be changed by the user based on need.

TABLE 1

| | effective data | | |
|---|---|---|---|
| | 0000 | 0010 | 0011 |
| controlling logic value | 1111110-1111110 | 1111110-1101101 | 1111110-1111001 |
| (abcdefg-abcdefg) | | | |

It is clear that although there are only three groups of effective datum and the corresponding controlling logic values for the at least one seven segment display 1031, the other sixteen groups of effective datum and the corresponding controlling logic values can be established by analogy.

The motherboard 30 transmits a real time status signal, the meaning of which is that there is a problem with the voltage regulator 27 of the second electric power supply module 22, to the protocol analysis module 1054. The real time status signal includes an effective data “0010”, which means that there is a problem with the voltage regulator 27 of the second electric power supply module 22.

The protocol analysis module 1054 analyzes the real time status signal from the motherboard 30 based on the SGPIO protocol, and determines the effective data is “0010”.

The data obtaining module 1055 obtains the effective data “0010” from the protocol analysis module 1054, and transmits the effective data “0010” to the determination module 1056.

The determination module 1056 receives the effective data “0010” from the data obtaining module 1055, and finds a controlling logic value “1111110-1101101” for the at least one seven segment LED display 1031, which corresponds to the effective data “0010”, and then transmits the controlling logic value “1111110-1101101” to the driving module 1057.

The driving module 1057 drives the at least one seven segment LED display 1031 to display “02” based on the controlling logic value “1111110-1101101”, such that it is shown that there is a problem with the voltage regulator 27 of the second electric power supply module 22. In alternative embodiments, the effect communication data “0000” may correspond to the controlling logic value “1111110-1101101”, the controlling logic value “1000111-1111001”, the controlling logic value “1000111-0110111”, etc. In such case, the display unit 103 correspondingly displays “02”, “F3”, “FH”, or other character(s), to show that the electric power supply modules are in a normal working status. In further alternative embodiments, the effective data “0010” may correspond to the controlling logic value “1111110-1111110”, the controlling logic value “1000111-1111001”, the controlling logic value “1000111-0110111”, etc. In such case, the display unit 103 correspondingly displays “00”, “F3”, “FH” or other character(s), to show that there is a problem with the voltage regulator 27 of the second electric power supply module 22.

When the number of the electric power supply module 22 is less than 9, there may be only one seven segment LED display 1031 available to display the real time status of the electric power supply modules. In such case, the display unit 103 can display the real time status of the power supply devices or the voltage regulators based on preset display information (e.g. 1, 3, A, H or other character(s)).

When the number of the electric power supply module 22 is less than or equal to 20, there may be two or three seven segment LED displays 1031 to display the real time status of the electric power supply modules. In such a case, the display unit 103 can display the real time status of the power supply devices or the voltage regulators based on preset display information (e.g. 26, 3A, B, 30A or other character(s)).

The test card 10 displays the real time status of the electric power supply modules via the at least one seven segment LED displays 1031. Accordingly, the user knows instantly that there is a problem with a certain electric power supply module, and the identity of the malfunctioning module is also revealed, by seeing numbers or characters displayed by the at least one seven segment LED displays 1031. The problem can thus be quickly solved, and working efficiency can thus be improved.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A test card for displaying a real time status of a plurality of electric power supply modules of a motherboard, comprising:
a display unit for displaying the real time status, the display unit comprising at least one seven segment LED display, the real time status comprising a normal working status and an abnormal working status if one of the electric power supply modules is not working normally, and
a programmable logic chip comprising a data table and a control unit, the data table comprising a plurality of preset effective datum and a plurality of preset controlling logic values for the at least one seven segment LED display corresponding to the preset effective datum, respectively, the control unit being configured for controlling the display unit to display the real time status, the control unit comprising:
a protocol analysis module for analyzing a real time status signal from the motherboard, and determining an effective data of the real time status signal;
a data obtaining module for obtaining the effective data from the protocol analysis module;
a determination module for receiving the effective data from the data obtaining module, and finding a controlling logic value for the at least one seven segment LED display in the data table, which corresponds to the effective data, and
a driving module for driving the at least one seven segment LED display to display the real time status based on the controlling logic value for the at least one seven segment LED display.

2. The test card of claim 1, wherein the number of the plurality of electric power supply modules is less than or equal to 20, and the number of the at least one seven segment LED display is two.

3. The test card of claim 1, wherein the number of the plurality of electric power supply modules is less than or equal to 9, and the number of the at least one seven segment LED display is one or two.

4. A motherboard monitoring system, comprising:
a motherboard, the motherboard comprising a plurality of electric power supply modules; and
a test card for displaying a real time status of the plurality of electric power supply modules, the test card comprising:
a display unit for displaying the real time status, the display unit comprising at least one seven segment LED display, the real time status comprising a normal working status and an abnormal working status if one of the electric power supply modules is not working normally, and
a programmable logic chip comprising a data table and a control unit, the data table comprising a plurality of preset effective datum and a plurality of preset controlling logic values for the at least one seven segment LED display corresponding to the preset effective datum, respectively, the control unit being configured for controlling the display unit to display the real time status, the control unit comprising:
a protocol analysis module for analyzing a real time status signal from the motherboard, and determining an effective data of the real time status signal;
a data obtaining module for obtaining the effective data from the protocol analysis module;
a determination module for receiving the effective data from the data obtaining module, and finding a controlling logic value for the at least one seven segment LED display in the data table, which is corresponding to the effective data, and
a driving module for driving the at least one seven segment LED display to display the real time status based on the controlling logic value for the at least one seven segment LED display.

5. The motherboard monitoring system of claim 4, wherein the real time status signal from the motherboard is a SGPIO signal.

6. The motherboard monitoring system of claim 4, wherein the motherboard further comprises a power management module electrically connected to the plurality of electric power supply modules, each of the electric power supply modules comprises a power supply device electrically connected to the power management module and a voltage regulator electrically connected to the power supply device and the power management, the real time status comprises a normal working status and an abnormal working status if one of the power supply device is not working normally or if one of the voltage regulator is not working normally.
